(19) United States
(12) Patent Application Publication
(10) Pub. No.: US 2011/0005796 A1
(43) Pub. Date: Jan. 13, 2011

(54) HOUSING AND METHOD FOR MAKING THE SAME

(75) Inventors: KUN-TSAN WU, Shindian (TW); LI-WEN TIEN, Shindian (TW)

Correspondence Address: Altis Law Group, Inc.;ATTN: Steven Reiss, 288 SOUTH MAYO AVENUE, CITY OF INDUSTRY, CA, 91789, US

(73) Assignee: FIH (HONG KONG) LIMITED, Kowloon (HK)

(21) Appl. No.: 12/570,094

(22) Filed: Sep. 30, 2009

(30) Foreign Application Priority Data
Jul. 10, 2009 (CN) 200910304238.2

(51) Int. Cl. H05K 5/02; B32B 38/10

(52) U.S. Cl. 174/50; 156/256

(57) ABSTRACT

A method for making a housing comprising: providing a metal layer, a decorative layer, and an adhesive layer; attaching adhesive layer to the decorative layer to form a preformed soft layer; cutting the preformed soft layer to form a soft layer having a configuration the same as that of the metal layer; attaching the soft layer to the metal layer to form a intermediate product; and heating and pressing the intermediate product by a thermo compressing apparatus to form the housing. The application also discloses a housing used in a portable electronic device.

### CROSS-REFERENCE TO RELATED APPLICATION

This application is related to co-pending U.S. Patent Application (Attorney Docket No. US26566, entitled “HOUSING AND METHOD FOR MAKING THE SAME”, by WU et al., which is the same assignee as the present application. The above-identified application is incorporated herein by reference.

BACKGROUND

1. Technical Field

The present disclosure relates to housings and methods for making the housings.

2. Description of Related Art

The housing for electronic devices can have a good tactility by forming a soft layer thereon. The soft layer is trimmed into a predetermined shape. The soft layer is attached to the housing by injection molding. However, the trimming process is costly and time consuming. Furthermore, the soft layer may subject to damage from the high temperatures of the injection molding.

Therefore, there is room for improvement within the art.

### BRIEF DESCRIPTION OF THE DRAWINGS

Many aspects of a housing and method making the same can be better understood with reference to the following drawings. The components in the drawings are not necessarily to scale, the emphasis instead being placed upon clearly illustrating the principles of the present housing and method making the same. Moreover, in the drawings, like reference numerals designate corresponding parts throughout the several views.

FIG. 1 is a cross-sectional view of a housing, according to an exemplary embodiment.

FIG. 2 is a cross-sectional view of the housing in manufacturing process.

### DETAILED DESCRIPTION OF THE EMBODIMENTS

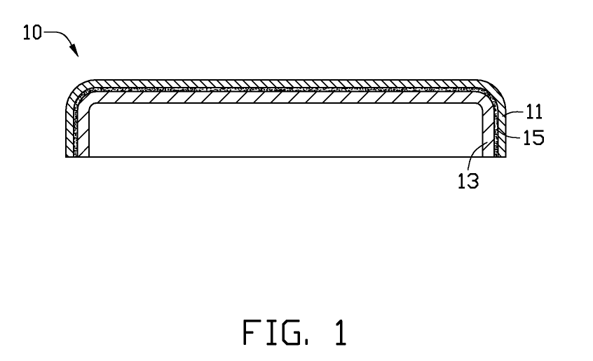

FIG. 1 shows a housing 10 used for a portable electronic device. The housing 10 includes a decorative layer 11, a metal layer 13, and an adhesive layer 15. The decorative layer 11 can be made of a soft material, such as leathers, fabrics, or plastics. The decorative layer 11 is attached to the metal layer 13 by the adhesive layer 15. The adhesive layer 15 is located between the decorative layer 11 and the metal layer 13. The housing 10 can be pressed and heated by a thermo compressing apparatus, thus, the decorative layer 11 is further tightly attached to the metal layer 13.

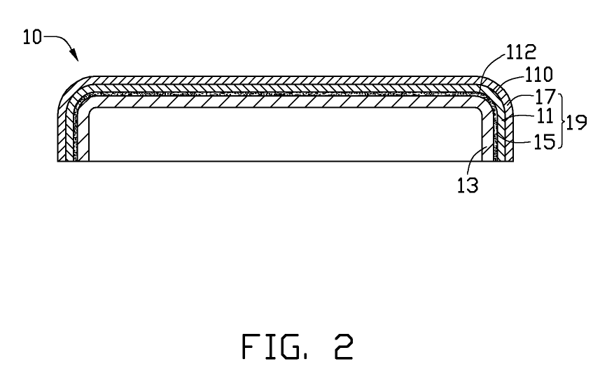

Referring to FIG. 2, during making of the housing 10, the decorative layer 11, the metal layer 13, the adhesive layer 15, a protective layer 17, a thermo compressing apparatus (not shown), and a computer numerical control machine (CNC) (not shown) are provided. The decorative layer 11 includes a first surface 110 and a second surface 112 opposite to the first surface 110. The first surface 110 has a plurality of decorative patterns (not shown).

The protective layer 17 and the adhesive layer 15 are respectively attached to the first surface 110 and the second surface 112. Accordingly, the decorative layer 11, the adhesive layer 15, and the protective layer 17 cooperatively serve as a soft layer 19. The soft layer 19 is attached to the metal layer 13 to form an intermediate product. Then the intermediate product is pressed and heated by the thermo compressing apparatus, and thus the adhesive layer 15 is tightly adhered to the metal layer 13 to form the housing 10. After the punching process, superfluous edges may occur on the housing 10. The superfluous edges can be cut away by the computer numerical control. At last, the protective layer 17 is removed and the first surface 110 is washed.

It can be understood that the metal layer 13 can be made of stainless steel, magnesium aluminium alloy, aluminium, or aluminium alloy. The protective layer 17 can be made of polyethylene (PE) or polyethylene terephthalate (PET). The adhesive layer 15 may include a medium denisty mixture of polyethylene (60%), polyisobutene (25%), butyl rubber (10%), and microcrystal wax (5%).

It is to be understood that, the adhesive layer 15 can be previously formed on the metal layer 13. Then, the decorative layer 11 can be attached to the adhesive layer 15.

It is to be understood that the protective layer 17 can be omitted. Accordingly, the step of washing the first surface can be omitted.

It is to be further understood that the adhesive layer 15 can alternatively be one of a double-faced adhesive belt, ultraviolet rays (UV) gum, and cyanoacrylate adhesive, etc.

It is to be further understood that the process of cutting the superfluous edges of the housing 10 can be omitted when the housing 10 does not require precision machining.

It is to be also understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for making a housing, comprising:
providing a metal layer, a decorative layer, and an adhesive layer;
attaching adhesive layer to the decorative layer to form a preformed soft layer;
cutting the preformed soft layer to form a soft layer having a configuration the same as that of the metal layer;
attaching the soft layer to the metal layer to form an intermediate product; and
heating and pressing the intermediate product using a thermo compressing apparatus to form the housing.

2. The method for making a housing as claimed in claim 1, further comprising attaching a protective layer to the decorative layer before cutting the preformed soft layer.

3. The method for making a housing as claimed in claim 2, further comprising cutting superfluous edges of the housing using a computer numerical control machine after the heating and pressing process.

4. The method for making a housing as claimed in claim 1, wherein the decorative layer is made of leathers, fabrics, or plastic.

5. A method for making a housing, comprising:
providing a metal layer, a decorative layer, and an adhesive layer;
cutting the decorative layer and the adhesive layer to have a configuration the same as that of the metal layer;
attaching the adhesive layer to the metal layer;
attaching the decorative layer to the adhesive layer, the adhesive layer, the decorative layer, and the metal layer to form an intermediate product; and
heating and pressing the intermediate product using a thermo compressing apparatus to form the housing.

6. The method for making a housing as claimed in claim 5, further comprising attaching a protective layer to the decorative layer before cutting the decorative layer and the adhesive layer.

7. The method for making a housing as claimed in claim 6, further comprising cutting superfluous edges of the housing using a computer numerical control machine after heating and pressing process.

8. The method for making a housing as claimed in claim 7, wherein the decorative layer is made of leathers, fabrics, or plastic.

9. A housing, comprising:
a decorative layer;
a metal layer; and
an adhesive layer adhering the decorative layer to the metal layer to form the housing by a thermo compressing apparatus.

10. The housing as claimed in claim 9, wherein the adhesive layer includes mixtures of medium density polyethylene 60%, polyisobutene 25%, butyl rubber 10%, and microcrystal wax 5%.

11. The housing as claimed in claim 9, wherein the adhesive layer is made of double faced adhesive tape, ultraviolet rays (UV) gum, or cyanoacrylate adhesive.

12. The housing as claimed in claim 9, wherein the decorative layer is made of leathers, fabrics, or plastic.

13. The housing as claimed in claim 9, wherein the metal layer is made of stainless steel, magnesium aluminium alloy, aluminium, or aluminium alloy.
